(19) United States
(12) Patent Application Publication
(10) Pub. No.: US 2010/0163294 A1
(43) Pub. Date: Jul. 1, 2010

(54) METHOD FOR FORMING METAL LINE OF SEMICONDUCTOR DEVICE

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/639,811

(22) Filed: Dec. 16, 2009

(30) Foreign Application Priority Data
Dec. 29, 2008 (KR) 10-2008-0135924

(51) Int. Cl. H05K 1/11; H01R 43/00

(52) U.S. Cl. 174/261; 29/847; 29/825; 438/669; 257/764

(57) ABSTRACT

A method of forming a metal line of a semiconductor device, and devices thereof. A method of forming a metal line of a semiconductor device may include forming a multi-layer structure over a substrate, forming a photoresist pattern over a multi-layer structure, forming a metal line by selectively etching a multi-layer structure using a photoresist pattern as an etching mask, removing an electron over a surface of a metal line by processing a surface of a metal line, and/or cleaning a metal line.

The present application claims priority under 35 U.S.C. 119 to Korean Patent Application No. 10-2008-0135924 (filed on Dec. 29, 2008) which is hereby incorporated by reference in its entirety.

### BACKGROUND

Embodiments relate to semiconductor technology. Some embodiments relate to a method of forming a metal line of a semiconductor device and devices thereof.

Recent progress of semiconductor fabrication technology and/or relative high integration of semiconductor devices may have increased demands of fineness and/or high precision of patterns formed over a substrate. Demands related to fineness of metal line sizes may have increased. As a result, there may have been research and/or studies addressing relative reduction of metal line size.

In a process of fabricating a semiconductor, a lower layer may be etched using a photoresist as an etching mask to form a metal line. A photoresist pattern may be formed by coating and/or exposing a photoresist on and/or over an etching object layer which may define a line forming area. A photoresist pattern may etch an etching object layer as etching mask such that a metal line may be formed. Ti and/or or TiN may be used as a passivation layer, which may be located on and/or over, and/or under, a metal line.

Copper, instead of for example aluminum, may be used to form a fineness of a metal line and/or instead of a I-line light source, deep ultra violet (DUV) light source having a relatively short wavelength may be used in a process of forming a mental line. However, when using a metal line formed of aluminum, an overall area of a metal line may be minimized, and/or electron saturation may occur due to electric characteristics of a metal line. In photoresist patterning etching and/or cleaning processes, electrons may be saturated and/or metal bomb may occur during etching and/or cleaning processes.

Reactive ion etching (RIE) using a photoresist pattern may be performed after a metal layer may be deposited. A cleaning process using inorganic chemicals may be performed using a rotating wafer. Electric charge may be recharged while a wafer may be rotating, and/or momentary reaction may occur when an inorganic chemical contacts a metal line having an electrical charge. There may be a bomb on and/or over relatively weak portions of a metal line. A possibility of a bomb may be relatively low when using amine chemicals, for example solvent, such bomb may occur using inorganic chemicals including deionized water (DIW) mixed with HF, H₂O₂ and/or H₂SO₄ that may have relatively low cost. Hydrogen ionized in inorganic chemicals fluid may be combined to electrons positioned in an outside area of a metal line and/or repulsive force may be activated to cause a momentary spark, such that a metal bomb may occur.

Accordingly, there is a need for a method of forming a metal line of a semiconductor device, and devices thereof.

### SUMMARY

Embodiments relate to a method of forming a metal line of a semiconductor device, and devices thereof. According to embodiments, a method of forming a metal line of a semiconductor device may be able to minimize metal bomb, which may be caused by electron saturation during etching and/or cleaning processes after photoresist patterning to form a metal line, which may be relatively fine. In embodiments, a method of forming a metal line of a semiconductor device may be able to remove electrons from a surface of a metal line, for example through metal line surface processing, after an etching process, by substantially preventing a chemical reaction between electrons and inorganic chemicals which may be used.

According to embodiments, a method of forming a metal line of a semiconductor device may include forming a metal line on and/or over a substrate. In embodiments, a method of forming a metal line of a semiconductor device may include forming a photoresist pattern on and/or over a metal line. In embodiments, a method of forming a metal line of a semiconductor device may include forming a metal line by selectively etching a metal line, for example using a photoresist pattern as an etching mask. In embodiments, a method of forming a metal line of a semiconductor device may include removing an electron on and/or over a surface of a metal line by processing a surface of a metal line. In embodiments, a method of forming a metal line of a semiconductor device may include cleaning a metal line.

According to embodiments, forming a metal line may include forming a first passivation layer on and/or over a substrate. In embodiments, forming a metal line may include forming a metal line layer for a metal line on and/or over a first passivation layer. In embodiments, forming a metal line may include forming a second passivation layer on and/or over a metal line layer. In embodiments, a first passivation layer may include Ti and/or a second passivation layer may include TiN. In embodiments, a meal line layer may be selectively etched using reactive ion etching (RIE) to form a metal line.

According to embodiments, electron removing may include metal line surface processing using hot deionized water (DIW) and/or O₃ chemicals to remove electrons from a surface of a metal line. In embodiments, a temperature of hot deionized water (DIW) may be maintained between approximately 60° C. and 90° C. during metal line surface processing. In embodiments, O3 chemicals may be configured of hydrochloric acid (HCI) and/or O3 water, which may be used as cleansing water. In embodiments, metal line surface processing using cleansing water may be performed for approximately 5 minutes or less.

### DRAWINGS

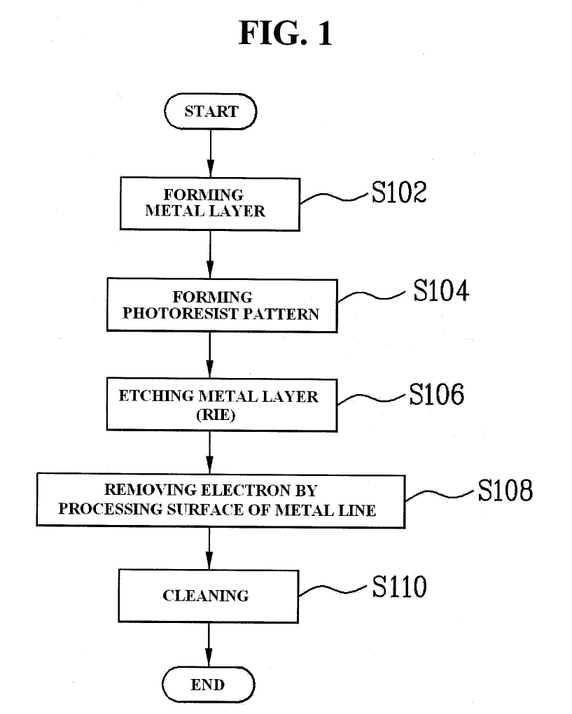

Example FIG. 1 is a flow chart illustrating a method of forming a metal line of a semiconductor device in accordance with embodiments.

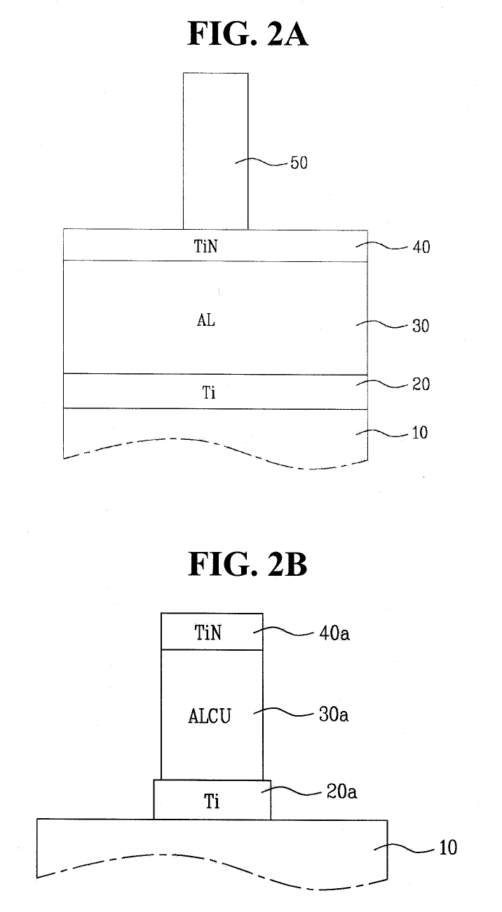

Example FIG. 2A and FIG. 2B are sectional views illustrating methods of forming a metal line in accordance with embodiments.

### DESCRIPTION

Embodiments relate to a method of forming a metal line of a semiconductor device, and devices thereof According to embodiments, a metal line may be formed. In embodiments, a metal line may be formed including aluminum. In embodiments, metal line surface processing may be performed to remove electrons from a surface of a metal line, for example after etching. In embodiments, a relatively rough surface of a metal line may be relatively improved in advance during surface processing. In embodiments, cleaning using inorganic chemicals may be performed.

Referring to example FIG. 1, a flow chart illustrates a method of forming a metal line of a semiconductor device in accordance with embodiments. Referring to example FIG. 2A and FIG. 2B, sectional views illustrate a method of forming a metal line in accordance with embodiments. According to embodiments, multi-layered type metal layers 20, 30 and/or 40 may be formed on and/or over substrate 10 (S102). In embodiments, for example to form multi-layered type metal layers, first passivation layer 20 may be formed of Ti on and/or over substrate 10. In embodiments, aluminum layer 30 for a metal line may be formed on and/or over first passivation layer 20. In embodiments, second passivation layer 40 may be formed of TiN on and/or over aluminum layer 30. In embodiments, various dielectric layers which may be employed as an reflection-prevention and/or projection layer, which may be used in an exposure and/or etching process, may be formed on and/or over second passivation layer 40.

According to embodiments, photoresist pattern 50 may be formed on and/or over multilayered type metal layers 20, 30 and/or 40. In embodiments, photoresist pattern 50 may be formed on and/or over second passivation layer 40 including TiN (S104). In embodiments, multi-layer type metal layers 20, 30 and/or 40 may be selectively etched using photoresist pattern 50 as etching mask (S106), such that a metal line may be formed.

According to embodiments, etched first passavation layer 20a including Ti may be formed under metal line 30a. In embodiments, etched second passivation layer 40a including TiN may be formed on and/or over metal line 30a. In embodiments, multi-layered type metal layers 20, 30 and 40 may be selectively etched using reactive ion etching (RIE), which may form a metal line. In embodiments, etching using plasma may be performed in a RIE process.

According to embodiments, remaining photoresist pattern used to etch may be substantially removed. In embodiments, cleaning may be performed after removing remaining photoresist pattern. In embodiments, processing a surface of metal line 30a may be performed prior to cleaning. In embodiments, a surface of metal line 30a may be processed after RIE employed to form metal line 30a, such that electrons may be removed from a surface of metal line 30a (S108).

According to embodiments, hot deionized water (DIW) and/or O₃ chemicals may be used to remove electrons from a surface of metal line 30a in metal line surface processing. In embodiments, a temperature of the hot DIW may be maintained approximately between 60° C. and 90° C. during surface processing. In embodiments, O₃ chemicals may process a surface of a metal line 30a within approximately 5 minutes, which may include hydrochloric acid (HCI) and/or O₃ water as cleaning water. In embodiments, electrons generated on a surface of a metal line by plasma during reactive ion etching (RIE) may be removed in advance, which may stabilize a surface of a metal line illustrated in the following example reaction formula.

e⁻+h⁺+O³+HIGH TEMPERATURE=STABILIZATION OF METAL LINE SURFACE EXAMPLE REACTION FORMULA

According to embodiments, hot DIW may melt and/or relatively improve a relatively rough surface of metal line 30a. In embodiments, cleaning may be performed for an overall substrate including a metal line (S110). In embodiments, inorganic chemicals mixed with HF, H₂O₂, H₂SO₄ and/or DIW may be used in a cleaning process. In embodiments, metal line surface processing may be performed prior to cleaning, such that bomb may not substantially occur in a metal line. In embodiments, electrons generated on and/or over an outer area of a metal line may be removed in advance, for example before they may react with hydrogen ionized in inorganic chemicals.

According to embodiments, remaining photoresist may be removed in an ashing process using plasma. In embodiments, metal line surface processing using hot DIW and/or O₃ chemicals may be performed after RIE which may form a metal line. In embodiments, electrons may be removed from a surface of a metal line and/or a relatively rough surface of a metal line may be relatively improved. In embodiments, a reaction of electrons with inorganic chemicals may be minimized. In embodiments, metal bomb may be minimized in advance.

According to embodiments, a method of forming a metal line of a semiconductor device may substantially prevent metal bomb which may occur in view of a desire for fineness of metal lines. In embodiments, relative reliability of a semiconductor device including a metal line may be maximized. In embodiments, metal line surface processing may substantially remove even polymer residue. In embodiments, electric performance of a semiconductor device may be relatively efficiently maximized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a multi-layer structure over a substrate;
forming a photoresist pattern over said multi-layer structure;
forming a metal line by selectively etching said multi-layer structure using said photoresist pattern as an etching mask;
removing an electron over a surface of said metal line by processing the surface of said metal line; and
cleaning said metal line.

2. The method of claim 1, wherein forming said multi-layer structure comprises:
forming a first passivation layer over the substrate;
forming a metal layer over said first passivation layer; and
forming a second passivation layer over said metal layer.

3. The method of claim 2, wherein said first passivation layer comprises Ti.

4. The method of claim 2, wherein said metal layer comprises an aluminum layer.

5. The method of claim 2, wherein said second passivation layer is comprises TiN.

6. The method of claim 1, wherein said multi-layer structure is selectively etched comprising reactive ion etching.

7. The method of claim 1, wherein said electron over said surface of said metal line is removed comprising metal line surface processing using hot deionized water and O₃ chemicals.

8. The method of claim 7, wherein a temperature of said hot deionized water is maintained between approximately 60° C. and 90° C. during said metal line surface processing.

9. The method of claim 7, wherein said O₃ chemicals include hydrochloric acid and O₃ water used as cleansing water.

10. The method of claim 9, wherein said metal line surface processing using said cleansing water is performed for approximately 5 minutes or less.

11. An apparatus comprising:
a metal line formed by selectively etching a multi-layer structure over a substrate using a photoresist pattern as an etching mask,
said metal line comprising a removed electron over a surface of said metal line formed by processing the surface of said metal line; and
said metal line comprising a cleaned metal line.

12. The apparatus of claim 11, wherein said multi-layer structure comprises:
a first passivation layer over the substrate;
a metal layer over said first passivation layer; and
a second passivation layer over said metal layer.

13. The apparatus of claim 12, wherein said first passivation layer comprises Ti.

14. The apparatus of claim 12, wherein said metal layer comprises an aluminum layer.

15. The apparatus of claim 12, wherein said second passivation layer is comprises TiN.

16. The apparatus of claim 11, wherein said multi-layer structure is selectively etched comprising reactive ion etching.

17. The apparatus of claim 11, wherein said electron over said surface of said metal line is removed comprising metal line surface processing using hot deionized water and O₃ chemicals.

18. The apparatus of claim 17, wherein a temperature of said hot deionized water is maintained between approximately 60° C. and 90° C. during said metal line surface processing.

19. The apparatus of claim 17, wherein said O₃ chemicals include hydrochloric acid and O3 water used as cleansing water.

20. The apparatus of claim 19, wherein said metal line surface processing using said cleansing water is performed for approximately 5 minutes or less.
